(19) United States
(12) Patent Application Publication
(10) Pub. No.: US 2025/0013796 A1
(43) Pub. Date: Jan. 9, 2025

(54) Subterranean and Linear Object Analysis Systems and Methods

(71) Applicant: The United States of America As Represented By The Director Of The National Geospatial-Intelligence

(72) Inventor: Gregory King, Springfield, VA (US)

(73) Assignee: The United States of America As Represented By The Director Of The National Geospatial-Intelligence, (omitted)

(21) Appl. No.: 18/346,340

(22) Filed: Jul. 3, 2023

(51) Int. Cl. G06F 30/13; G01V 20/00

(52) U.S. Cl. CPC G06F 30/13; G01V 20/00

(57) ABSTRACT

Systems and methods for identifying low cost subterranean paths are presented. Travel costs are assigned to areas of a 3D subterranean model based on geographic and man-made conditions. The model is analyzed to identify low cost paths of travel between points, from an area to a point and vice versa, and between multiple points in a given area. This analysis can be used to help inform planning for the construction of subterranean transport networks such as utility lines and tunnels by highlighting paths with the lowest costs. Similarly, this analysis can be used to identify likely locations for preexisting paths so that they can be explored or interdicted.

### STATEMENT OF GOVERNMENT INTEREST

The invention described herein was made by employees of the United States Government and may be manufactured and used by or for the Government for Government purposes without payment of any royalties.

### BACKGROUND OF THE INVENTION

Subterranean and linear object analysis is a key enabler to multiple fields of endeavor. Archaeologists, civil engineers, civic planners, law enforcement officials, and security professionals can use these analyses to support a wide range of activities from identifying locations of ancient tunnels between Egyptian tombs to interdicting human traffickers and smugglers to facilitating access to subterranean points of interest such as historic sites to identifying lowest cost options for subterranean transport networks such as utility corridors, subways, and highway or rail tunnels. Identifying lowest-cost paths and points of intersection in complex terrain helps professionals efficiently exploit and interdict the subterranean environment to enable or restrict movement for a variety of purposes.

### SUMMARY OF THE INVENTION

The following presents a simplified summary of the disclosure in order to provide a basic understanding to the reader. This summary is not an extensive overview of the disclosure and it does not identify key/critical elements or delineate the scope of the specification.

As used herein, the term “includes” and its variants are to be read as open terms that mean “includes, but is not limited to.” The term “based on” is to be read as “based at least in part on.” The term “one embodiment” and “an embodiment” are to be read as “at least one embodiment.” The term “another embodiment” is to be read as “at least one other embodiment.” Other definitions, explicit and implicit, may be included below.

The present application is directed to systems and methods for subterranean and linear object analyses that can be used to identify lowest-cost paths in support of identifying existing tunnels, planning new tunnels, identifying areas and pathways of high risk or reward, and other similar efforts.

Multiple embodiments are described below.

Many of the attendant features will be more readily appreciated by reference to the following detailed description and the accompanying drawings.

### BRIEF DESCRIPTION OF DRAWINGS

The present description will be better understood from the following detailed description read in light of the accompanying drawings, wherein:

FIG. 1 is a flow chart of a method for performing a subterranean analysis;

FIG. 2 is an illustration of a 3D section view of an area of interest;

FIG. 3 is an illustration of a 3D section view of an area of interest;

FIG. 4 is an illustration of an exemplary computing-based device.

### DETAILED DESCRIPTION OF THE INVENTION

The detailed description provided below in connection with the appended drawings is intended as a description of the present examples and is not intended to represent the only forms in which the present example may be constructed or utilized. The description sets forth the functions of the example and the sequence of steps for constructing and operating the example. However, the same or equivalent functions and sequences may be accomplished by different examples. Further, various illustrated or described portions of processes may be re-ordered or executed in parallel in various different embodiments.

As used herein, the term “subterranean” refers to objects, entities, or activities below an elevation defined by a digital elevation model or other elevation model. In some embodiments, subterranean may include one or more areas under a water surface such as a river, lake, or ocean. In some embodiments, objects, entities, or activities that may be colloquially referred to as underwater may fall within the definition of subterranean.

As used herein, the term “linear object” refers to a real or virtual object that may be represented by a series of points that may generally be connected by a single path. A linear object may have multiple dimensions (e.g., width, height, and length) and may comprise vertical and horizontal curves.

The present application is directed to systems and methods for performing subterranean and linear object analyses for an identified geographic area, also referred to as an area of interest (AOI). These analyses are used to identify low cost paths of travel between points, from an area to a point and vice versa, and between multiple points in a given AOI. These analyses can also identify low cost areas for traversing a subterranean plane. All of these analyses can be used to help inform planning for the construction of subterranean transport networks such as utility lines and tunnels by highlighting paths and points of intersection with the lowest costs. Similarly, these analyses can be used to identify likely locations for preexisting paths and points of intersection so that they can be explored or interdicted.

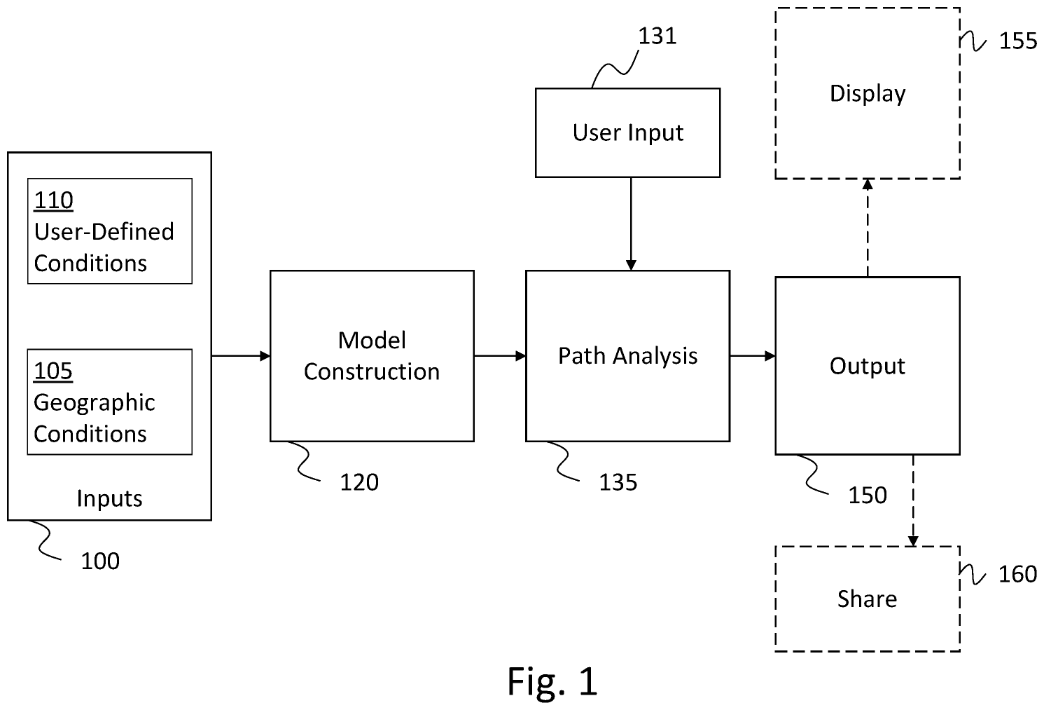

FIG. 1 is a flow chart of a method for performing a subterranean analysis. Inputs 100 include geographic conditions 105 and user-defined conditions 110. Geographic conditions 105 are combined with user-defined conditions 110 to build a digital model 120 of the subterranean area to be analyzed. Path analysis 135 of the model 120 may also incorporate user input 131. Once path analysis 135 is complete, output 150 is generated and optionally displayed 155 to one or more users. Displaying 155 the output 150 to one or more users may be accomplished using any one or more of: a visual display; a printed report; and audible signal; a natural user interface; an augmented or virtual reality system; or any other method known in the art. Output 150 may also be shared 160 with one or more of: a user; another system; a log; or any other human or non-human recipient known in the art.

Geographic conditions 105 include ground surface elevations, water surface elevations, water table elevations, frost line elevations, elevations and extents of soil and rock layers, locations of subterranean utilities, barriers, basements, storm cellars, and other man-made features, and any other similar information. Geographic conditions 105 may be input in the form of one or more elevation models. In one embodiment, geographic conditions 105 are input as one or more rasters.

User-defined conditions 110 include numerical representations of the relative difficulty of traversing a given geographic element, such as a particular rock or soil type. These numerical representations are also referred to as travel costs. Travel costs may be input by any one or more of the following methods; manually by a user, imported from a database, determined by a system, through any other appropriate means known in the art, or through any combination of methods. In embodiments where travel costs are imported from a database, the travel cost may be imported based on any one or more of the elevation of the given geographic element, the elevation of a water table or frost line relative to the elevation of the given geographic element, an identifier associated with the given geographic element (e.g., “granite” or “silt” or “culvert”), or any other appropriate method known in the art. In embodiments where travel costs are determined by a system, the travel costs may be determined based on any one or more of; data from prior analyses of the same or similar regions, interpolation or extrapolation from data for adjacent geographic elements, or any other appropriate method known in the art. Travel costs entered manually by a user may be based on any of the considerations identified above or other appropriate considerations.

In one embodiment, a travel cost that increases the cost of travel near the ground surface or near the intersection of a rock/soil layer and a body of water may be added manually, imported, or determined by a system. This travel cost increase may be used to model the increased risk of cave in or detection of subterranean travel paths in those areas. In one embodiment, the same geographic element may have different travel costs based on whether the element is being traversed vertically or horizontally. In one embodiment, the travel costs are multipliers. More information regarding this embodiment is provided below.

User-defined conditions 110 also include a minimum elevation below which no analysis is performed and at least one resolution value. In one embodiment, the resolution value for the horizontal (X and Y) axes is different from the resolution value for the vertical (Z) axis. In one embodiment, a single resolution value is used for the X, Y, and Z axes of the model being constructed. In one embodiment, at least one of the resolution values is the lowest resolution value of the input elevation models. In one embodiment, at least one of the resolution values is set to a value lower than the lowest resolution value of the input elevation models. In this embodiment, the at least one resolution value may be set by a user, automatically based on one or more pre-defined criteria (e.g., processing or storage capacity), or through any appropriate method known in the art. In one embodiment, at least one resolution value higher than the lowest resolution value of the input elevation models may be specified by a user, automatically (as discussed above or based on the highest resolution value of the input elevation models), or using any other appropriate method known in the art. Methods for combining models with different resolution values are discussed further below with respect to combining analyses performed at different resolution values. These techniques, or any other appropriate techniques known in the art, may be used to combine models with different resolution values prior to analysis.

Model construction 120 includes creating a digital model of the AOI between the minimum elevation and the ground or water surface(s). The digital model comprises 3D voxels representing the geographic conditions 105 and their associated user-defined conditions 110. The resolution (i.e., size and density) of the voxels is determined by the resolution values discussed above.

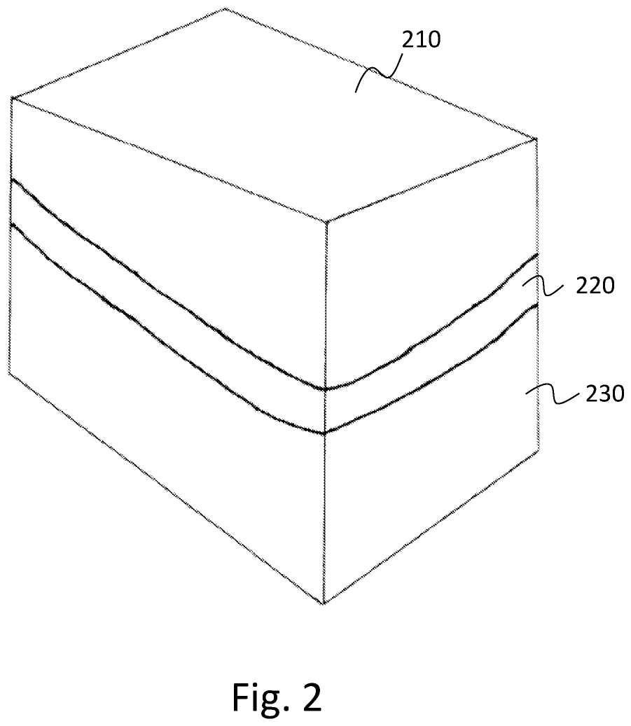

FIG. 2 is an illustration of a 3D section view of an AOI consisting of a lake 210 on top of a bed of silt 220 on top of a layer of sandstone 230. A model of the AOI illustrated in FIG. 2 would consist of: a plurality of voxels with travel costs associated with sandstone between the model's minimum elevation and the elevation of the interface between the sandstone and the silt layers; a plurality of voxels with travel costs associated with silt between the elevation of the interface between the sandstone and silt layers and the elevation of the interface between the silt and lake layers; and a plurality of voxels with travel costs associated with water between the elevation of the interface between the silt and lake layers and the elevation of the lake surface.

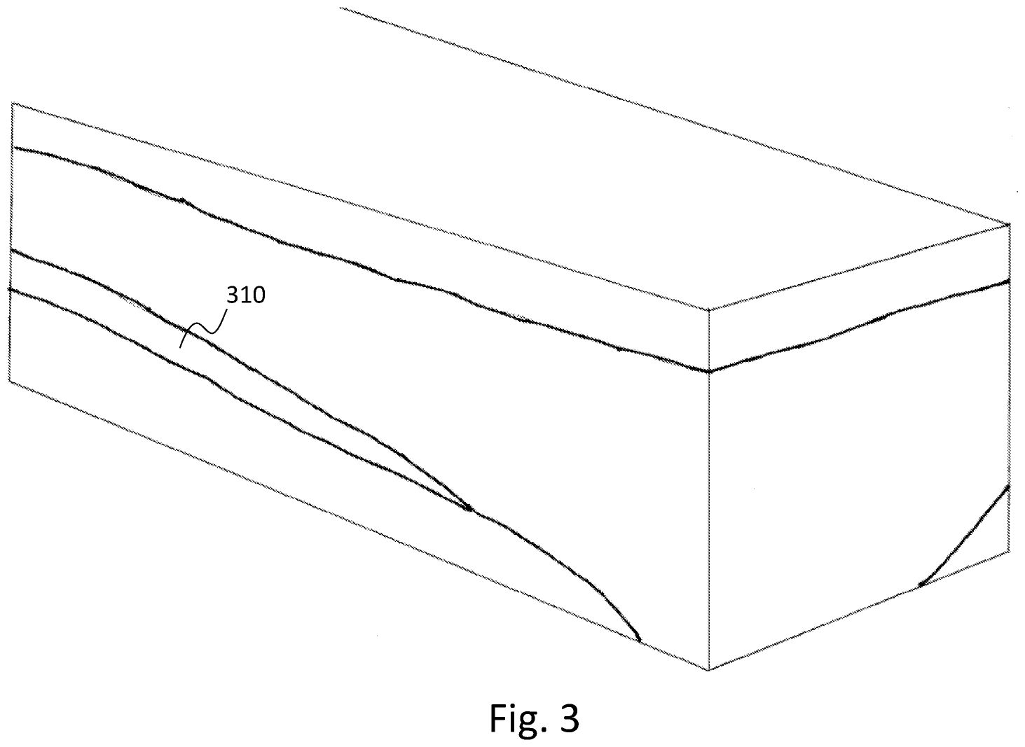

In various embodiments, the number of model layers may vary based on the horizontal (X, Y) location. For example, FIG. 3 is an illustration of a 3D section view of an AOI in which the height of layer 310 decreases as you move from left to right along the section until, near the right side of the section, layer 310 is not present at all.

For embodiments where the travel costs are multipliers, a voxel with a plurality of travel costs would have a total travel cost that is the product of the plurality of travel costs. For example, for a voxel representing a layer of silt below the water table where the travel cost for silt is 2 and the travel cost for areas below the water table is 5, the total travel cost for the voxel would be 10. In other embodiments, the travel costs may be combined through simple addition or through any other appropriate method known in the art.

Path analysis 135 may be used to determine the lowest cost paths between one or more user defined start points and one or more user defined end points. In one embodiment, the elevation of the start and end points is assumed to be the top of the uppermost voxel at the given horizontal (X and Y) location. In other embodiments, the elevations of the start and end points are determined by a user. In one embodiment, a maximum path length is determined by a user or system using any of the methods discussed above for determining travel costs. In these embodiments, paths whose length would exceed the maximum will not be considered.

Path analysis 135 may also be used to determine the lowest cost paths to or from one or more user defined start or end points. In one embodiment, the lowest cost paths are determined based on a start or end point, an initial path direction, and a directional cone. In this embodiment, the path analysis starts from the identified point and proceeds in the identified initial path direction. The path may deviate from the initial path direction within the limits of the directional cone, in order to minimize cost. The orientation of the directional cone may remain constant relative to the initial path direction or may vary as the path is created. In embodiments where the orientation of the directional cone varies, the orientation may be based on the orientation of a line from the current voxel to any of the preceding voxels along the path. The total path length may be limited by any one or more of: a maximum total path distance, a maximum cost, a maximum distance from the identified point (e.g., maximum radius), a maximum time to build a tunnel or other passage along the path, the path intersecting with a boundary, or any other appropriate limitation known in the art. These path length limitations may be used with any other embodiment described in this specification that may use a maximum path length.

In this embodiment, the start or end point, initial path direction, directional cone, and any of the path length limitations may be specified by a user or system. Information specified by a user may be included in user input 131. Systems used to specify information in this embodiment may be the same as or similar to other systems discussed elsewhere in this specification or using any other appropriate methods known in the art. The initial path direction may be based on any one or more of: a user input direction, the relative cost of travelling through the voxels adjacent to the start or end point, the direction to a point of interest, the range of directions toward an area of interest, the direction to the centroid of an area of interest, or any other appropriate criteria known in the art. The directional cone may be specified as an angle or slope measured from the path direction. The directional cone may have a constant angle or slope, creating a cone with a circular cross section, or the directional cone may have an angle or slope that differs for the horizontal and vertical planes, creating a cone with a rectangular cross section.

In embodiments where the path length is limited by a maximum time to build a tunnel or other passage along the path, the maximum time may be specified by a user input 131 or by a system as described elsewhere in this specification. In these embodiments, the time needed to build the tunnel or other passage may be based on one or more rates of construction provided as part of user input 131 or user-defined conditions 110. In these embodiments, the rates of construction may be associated with the geographic conditions 105 for the voxels along the path. For example, a voxel comprising clay may have a rate of construction that is faster than the rate of construction for a voxel comprising granite. In some embodiments, the time is based on one or more cross-sections and associated rates of construction provided as part of user input 131 or user-defined conditions 110. For example, the time needed to construct a unit length of tunnel with a 10-foot by 10-foot cross section may be based on a weighted average of the rates of construction for the materials (soil, rock, etc.) within the cross-section. In addition, the time needed may also include a multiplier to represent the increased complexity of constructing a tunnel with such a large cross section.

In one embodiment, a path analysis may comprise a first directional cone starting at a start point and oriented toward an end point and a second directional cone starting at the end point and oriented toward the start point. In this embodiment, the paths analyzed must be contained completely within the overlapping volume of the two directional cones.

In one embodiment, the lowest cost paths are determined using Dijkstra's algorithm. Another embodiment may use the A* (or “A-Star”) algorithm. Other embodiments may use other appropriate methods known in the art or combinations of methods. In one embodiment, costs for a given path are calculated from the start point to the end point and from the end point to the start point. In other embodiments, the cost may be calculated in only one direction.

Output 150 may include analysis results for all paths, only the lowest cost path(s) or a subset of paths within a given cost range of the lowest cost path. In embodiments where output 150 includes a subset of results, the subset may be defined using any appropriate method known in the art including percentage offsets, standard deviations, constant offsets, etc. In embodiments where output 150 includes more than one result, the results displayed 155 or shared 160 may include all results in output 150 or only a subset of those results. In embodiments where only a subset is displayed 155 or shared 160, the subset displayed 155 may be different from the subset shared 160. In all embodiments including a subset, the values used to define the subset may be determined manually by a user or automatically by a system using any of the methods discussed above or any other appropriate method known in the art.

In one embodiment, a 2D heat map is generated based on cost analyses of multiple paths. The 2D map is a projection onto the horizontal (X, Y) plane of the voxels created during model construction 120. The value of each cell in the 2D map is a summation of the inverse cost of each path that crosses a voxel projected onto that cell. A high number of low cost paths passing below a given cell will increase the value of that cell. Accordingly, higher cell values indicate a higher likelihood that the cell is a candidate for a subterranean path. This 2D heat map provides a simple graphic depiction of locations within the AOI that have a higher likelihood of containing existing subterranean paths or may be candidates for new subterranean paths between the analyzed start and end points. in some embodiments, the 2D map may be projected onto a plane that is parallel with a ground surface of all or part of the AOI.

In one embodiment, the path analyses used to generate the 2D heat map may have been performed at different times, at different resolutions, or on different models of the same geographic area. In one embodiment, the voxel resolution may be modified to smooth the results of the path analyses and blend the costs of several nearby paths. In this embodiment, the voxel resolution modification may be determined manually by a user or determined automatically by a system. In embodiments where the voxel resolution modification is determined manually by a user, the modification may be based on a user-defined voxel or pixel resolution, a ratio of the number of pixels to the area analyzed, or any other appropriate input metric known in the art. In embodiments where the voxel resolution modification is determined automatically by a system, the modification may be based on the voxel resolutions of the paths analyzed (e.g., lowest resolution, average resolution, median resolution, weighted average of resolutions using inverse cost as the weight, or any other appropriate method known in the art), density of the paths analyzed (e.g., decreasing resolution to combine paths within a threshold distance of each other that have costs within a threshold value of each other), or any other appropriate method known in the art.

In embodiments where output 150 includes a 2D heat map, the heat map may be displayed 155 or shared 160 as discussed above.

In one embodiment, path analysis 135 includes a cross section cost analysis. In this embodiment, user input 131 includes coordinates or a relative position of a vertical cross section through a portion of the AOI, including a minimum depth which may be the same or different from the minimum depth of the model. In this embodiment, the identified cross section is divided into a 2D mesh. The size of the mesh may be determined based on the voxel resolution or determined manually or automatically using any of the methods identified above. Each pixel of the mesh is used as an intermediate point between a user defined start point and end point. A cost analysis is performed for the plurality of paths from the start point to the end point passing through each intermediate point. In one embodiment, the cost of a path through a given intermediate point is the sum of the costs of the path from the start point to the intermediate point and the path from the end point to the intermediate point. In other embodiments, the cost through a given intermediate point may be determined using any appropriate method known in the art. In one embodiment, the cost information for the cross section may be refined by using linear interpolation, or other appropriate analytic techniques, to approximate the cost of crossing the cross section at points between the identified intermediate points.

In one embodiment, a cross section cost analysis is performed using a plurality of paths with one or more start points and a maximum path length. In this embodiment, the number of paths is such that at least one path intersects each pixel of the 2D mesh, as discussed above. Other aspects of path formation and cost determination are as stated above.

In embodiments where path analysis 135 includes a cross section cost analysis, output 150 may include displaying the costs to one or more users. The costs may be displayed as a matrix, heat map, or using any other appropriate method known in the art. The costs displayed may include only the calculated costs, or a combination of calculated costs and the approximated costs discussed above. The costs may also be shared using any of the methods discussed above.

The cross-section costs may be used to help identify locations within the cross section that have a higher likelihood of containing existing subterranean paths or that may be candidates for new subterranean paths between the analyzed start and end points.

In one embodiment, a plurality of cross section analyses with different start points and different end points from each other may be performed on the same or similar cross sections. In this embodiment, the inverse of the calculated or approximated costs for the same location on the cross section may be combined, similar to the method for generating the 2D heat map discussed above. In this embodiment, portions of the cross section that do not have cost data for each of the plurality of analyses may be omitted to prevent skew in the combined cost data. The combined costs generated in this embodiment may be output 150, displayed 155, and shared 160 as discussed above.

In one embodiment, path analyses may be performed for a plurality of start points representing one or more contiguous start areas and a single end point. In this embodiment, each start area is divided into a 2D grid. The size of the grid may be determined based on the voxel resolution or determined manually or automatically using any of the methods identified above regarding 2D mesh or voxel resolutions. Each point of the start area grid(s) is used as a start point. A cost analysis is performed for the plurality of paths from the start points to the end point or to the maximum path length. The cost of the lowest cost path for each start point is mapped to the corresponding start point.

In one embodiment, the cost information for the start area(s) may be refined by using linear interpolation, or other appropriate analytic techniques, to approximate the cost values of points between the identified grid points. In one embodiment, output 150 may include a matrix or database of point coordinates and associated cost values that may be displayed 155 or shared 160 as discussed above. In this embodiment, the points may be the grid points, approximated points discussed above, or a combination of both.

In one embodiment, output 150 may include a heat map that is displayed 155 or shared 160 as discussed above. In this embodiment, the heat map may be based on the costs at the grid points, approximated points discussed above, or a combination of both.

Embodiments incorporating analyses of start areas as discussed above may be useful for identifying low cost paths to a subterranean mineral deposit, identifying likely paths to or from an identified subterranean access point (e.g., an entrance to a tunnel used for smuggling), and other similar efforts.

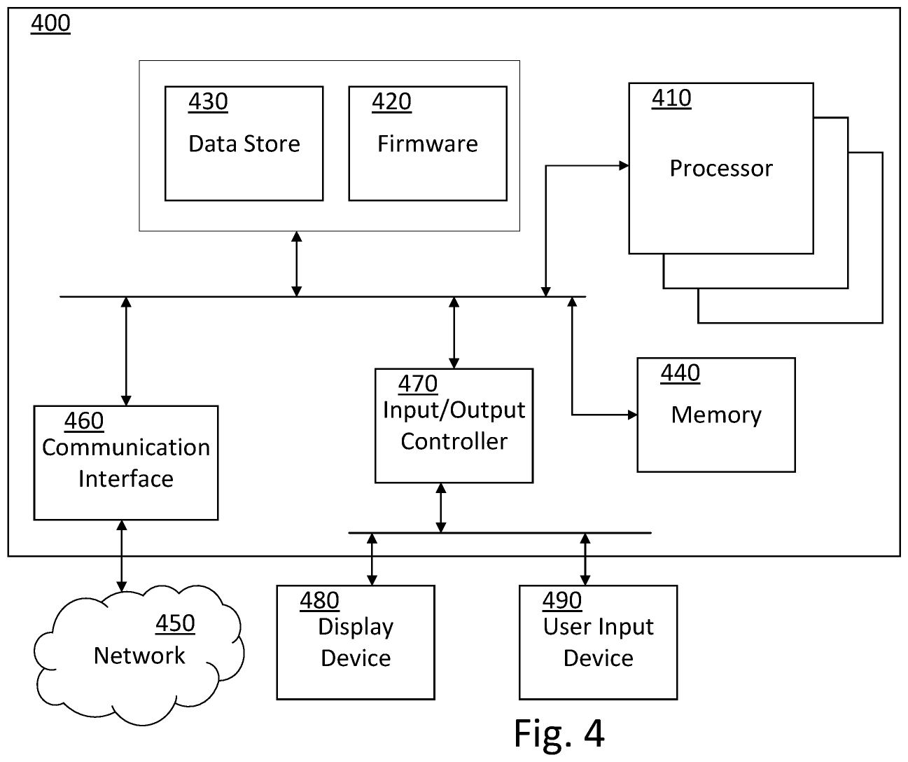

FIG. 4 illustrates various components of an exemplary computing-based device 400 which may be implemented as any form of a computing and/or electronic device, and in which embodiments of a controller may be implemented.

Computing-based device 400 comprises one or more processors 410 which may be microprocessors, controllers or any other suitable type of processors for processing computer executable instructions to control the operation of the device. In some examples, for example where a system on a chip architecture is used, the processors 410 may include one or more fixed function blocks (also referred to as accelerators) which implement a part of controlling one or more embodiments discussed above. Firmware 420 or an operating system or any other suitable platform software may be provided at the computing-based device 400. Data store 430 is available to store sensor data, parameters, logging regimes, and other data.

The computer executable instructions may be provided using any computer-readable media that is accessible by computing based device 400. Computer-readable media may include, for example, computer storage media such as memory 440 and communications media. Computer storage media, such as memory 440, includes volatile and non-volatile, removable and non-removable media implemented in any method or technology for storage of information such as computer readable instructions, data structures, program modules or other data. Computer storage media includes, but is not limited to, RAM, ROM, EPROM, EEPROM, flash memory or other memory technology, CD-ROM, digital versatile disks (DVD) or other optical storage, magnetic cassettes, magnetic tape, magnetic disk storage or other magnetic storage devices, or any other non-transmission medium that can be used to store information for access by a computing device. In contrast, communication media may embody computer readable instructions, data structures, program modules, or other data in a modulated data signal, such as a carrier wave, or other transport mechanism. As defined herein, computer storage media does not include communication media. Therefore, a computer storage medium should not be interpreted to be a propagating signal per se. Propagated signals may be present in a computer storage media, but signals per se, propagated or otherwise, are not examples of computer storage media. Although the computer storage media (memory 440) is shown within the computing-based device 400 it will be appreciated that the storage may be distributed or located remotely and accessed via a network 450 or other communication link (e.g. using communication interface 460).

The computing-based device 400 also comprises an input/output controller 470 arranged to output display information to a display device 480 which may be separate from or integral to the computing-based device 400. The display information may provide a graphical user interface. The input/output controller 470 is also arranged to receive and process input from one or more devices, such as a user input device 490 (e.g. a mouse, keyboard, camera, microphone, or other sensor). In some examples the user input device 490 may detect voice input, user gestures or other user actions and may provide a natural user interface. This user input may be used to change parameter settings, view logged data, access control data from the device such as battery status and for other control of the device. In an embodiment the display device 480 may also act as the user input device 490 if it is a touch sensitive display device. The input/output controller 470 may also output data to devices other than the display device, e.g. a locally connected or network-accessible printing device. The input/output controller 470 may also connect to various sensors discussed above, and may connect to these sensors directly or through the network 450.

The input/output controller 470, display device 480 and optionally the user input device 490 may comprise NUI technology which enables a user to interact with the computing-based device in a natural manner, free from artificial constraints imposed by input devices such as mice, keyboards, remote controls and the like. Examples of NUI technology that may be provided include but are not limited to those relying on voice and/or speech recognition, touch and/or stylus recognition (touch sensitive displays), gesture recognition both on screen and adjacent to the screen, air gestures, head and eye tracking, voice and speech, vision, touch, gestures, and machine intelligence. Other examples of NUI technology that may be used include intention and goal understanding systems, motion gesture detection systems using depth cameras (such as stereoscopic camera systems, infrared camera systems, RGB camera systems and combinations of these), motion gesture detection using accelerometers/gyroscopes, facial recognition, 3D displays, head, eye and gaze tracking, immersive augmented reality and virtual reality systems and technologies for sensing brain activity using electric field sensing electrodes (EEG and related methods).

The embodiments described above may be used in any combination without departing from the scope of the specification, and may be implemented using any form of appropriate computing-based device.

The term ‘computer’ or ‘computing-based device’ is used herein to refer to any device with processing capability such that it can execute instructions. Those skilled in the art will realize that such processing capabilities are incorporated into many different devices and therefore the terms ‘computer’ and ‘computing-based device’ each include PCs, servers, mobile telephones (including smart phones), tablet computers, wearable devices, set-top boxes, media players, games consoles, personal digital assistants and many other devices.

This acknowledges that software can be a valuable, separately tradable commodity. It is intended to encompass software, which runs on or controls “dumb” or standard hardware, to carry out the desired functions. It is also intended to encompass software which “describes” or defines the configuration of hardware, such as HDL (hardware description language) software, as is used for designing silicon chips, or for configuring universal programmable chips, to carry out desired functions.

Those skilled in the art will realize that storage devices utilized to store program instructions can be distributed across a network. For example, a remote computer may store an example of the process described as software. A local or terminal computer may access the remote computer and download a part or all of the software to run the program. Alternatively, the local computer may download pieces of the software as needed, or execute some software instructions at the local terminal and some at the remote computer (or computer network). Those skilled in the art will also realize that by utilizing conventional techniques known to those skilled in the art that all, or a portion of the software instructions may be carried out by a dedicated circuit, such as a DSP, programmable logic array, or the like.

Any range or device value given herein may be extended or altered without losing the effect sought, as will be apparent to the skilled person.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item refers to one or more of those items.

The steps of the methods described herein may be carried out in any suitable order, or simultaneously where appropriate. Additionally, individual blocks may be deleted from any of the methods without departing from the spirit and scope of the subject matter described herein. Aspects of any of the examples described above may be combined with aspects of any of the other examples described to form further examples without losing the effect sought.

The term ‘comprising’ is used herein to mean including the method blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments and/or combine any number of the disclosed embodiments without departing from the spirit or scope of this specification.

1. A method of identifying a low cost subterranean path between two points, the method comprising:
accessing a digital 3D model of an area of interest;
generating one or more paths between one or more start points and one or more end points;
assigning a cost to each of the one or more paths, the cost being based at least in part on one or more travel costs associated with one or more portions of the digital 3D model; and
at least one of:
displaying one or more of the assigned costs to a user; or
sharing one or more of the assigned costs with a non-human recipient.

2. The method of claim 1, wherein the digital 3D model comprises a plurality of voxels and each voxel has an assigned travel cost, the assigned travel cost based at least in part on one or more geographic conditions.

3. The method of claim 2, wherein the one or more geographic conditions comprise at least one of:
elevations and extents of soil layers; or
elevations and extents of rock layers.

4. The method of claim 2, wherein the assigned travel cost is further based at least in part on an identifier associated with a geographic element corresponding to the voxel.

5. The method of claim 1, wherein the one or more paths between a given start point and a given end point are completely contained within the overlapping volume of a first and a second directional cone, the first directional cone originating at the given start point and oriented toward the given end point, and the second directional cone originating at the given end point and oriented toward the given start point.

6. The method of claim 1, wherein the one or more paths are determined using at least one of Dijkstra's Algorithm or the A-Star Algorithm.

7. The method of claim 1, wherein the cost of a given path is based on a first cost calculated from a start point to an end point and a second cost calculated from the end point to the start point.

8. The method of claim 1 further comprising generating a 2D heat map, generating the 2D heat map comprising:
for each voxel associated with one or more paths, calculating the sum of the inverse of the travel costs for each path associated with the voxel; and
projecting the sum for each voxel onto a horizontal plane.

9. The method of claim 1 further comprising determining the costs of crossing a given cross section, the determination comprising:
dividing the given cross section into a 2D mesh;
generating a plurality of paths between the one or more start points and the one or more end points such that at least one generated path passes through each pixel of the 2D mesh; and
calculating the cost of each path.

10. The method of claim 1 wherein the one or more paths are between a plurality of start points and a single end point, the plurality of start points being arranged in a 2D grid within the boundaries of a given start area.

11. A method of identifying a low cost subterranean path, the method comprising: [only specifying start or end point, not both] accessing a digital 3D model of an area of interest;
generating one or more paths with a start point and a maximum path length;
assigning a cost to each of the one or more paths, the cost being based at least in part on one or more travel costs associated with one or more portions of the digital 3D model; and
at least one of:
displaying one or more of the assigned costs to a user; or
sharing one or more of the assigned costs with a non-human recipient.

12. The method of claim 11, wherein the digital 3D model comprises a plurality of voxels and each voxel has an assigned travel cost, the assigned travel cost based at least in part on one or more geographic conditions.

13. The method of claim 12, wherein the one or more geographic conditions comprise at least one of:
elevations and extents of soil layers; or
elevations and extents of rock layers.

14. The method of claim 12, wherein the assigned travel cost is further based at least in part on an identifier associated with a geographic element corresponding to the voxel.

15. The method of claim 11, wherein at least one of the one or more paths are completely contained within the volume of a directional cone, the directional cone originating at the start point and at least initially oriented in an initial path direction.

16. The method of claim 11, wherein the one or more paths are determined using at least one of Dijkstra's Algorithm or the A-Star Algorithm.

17. The method of claim 11, wherein the maximum path length is based at least in part on a maximum construction cost.

18. The method of claim 11 further comprising generating a 2D heat map, generating the 2D heat map comprising:
for each voxel associated with one or more paths, calculating the sum of the inverse of the travel costs for each path associated with the voxel; and
projecting the sum for each voxel onto a horizontal plane.

19. The method of claim 11 further comprising determining the costs of crossing a given cross section, the determination comprising:
dividing the given cross section into a 2D mesh;
generating a plurality of paths from the one or more start points such that at least one generated path passes through each pixel of the 2D mesh; and
calculating the cost of each path.

20. The method of claim 11 further comprising a plurality of start points arranged in a 2D grid within the boundaries of a given start area.
